(19) United States
(12) Patent Application Publication
(10) Pub. No.: US 2015/0271934 A1
(43) Pub. Date: Sep. 24, 2015

(54) Repositionable Orbiting Outlet Electrical Box Assembly

(71) Applicants: James Matthew Hardage, Benton, AR (US); David Jack Brown, Little Rock, AR (US); Thomas Noel Farmer, Benton, AR (US)

(72) Inventors: James Matthew Hardage, Benton, AR (US); David Jack Brown, Little Rock, AR (US); Thomas Noel Farmer, Benton, AR (US)

(21) Appl. No.: 14/221,266

(22) Filed: Mar. 20, 2014

(51) Int. Cl. H05K 5/02; H02G 3/10; H02G 3/18

(52) U.S. Cl. CPC H05K 5/0217; H02G 3/18; H02G 3/10

(57) ABSTRACT

A moveable rotating electrical box assembly, which adheres to a wall that provides a housing for standard electrical outlet (prior art), GFCI electrical outlet (prior art) and other various prior art electrical outlet types. The electrical outlet box housing is connected to a tubular wire housing by a rotating collar. The rotating collar allows the electrical box to rotate in a desired orientation. The tubular wire housing extends towards an existing outlet. The tubular wire housing flanges at the end closest to an existing outlet to accommodate a rotating plug (prior art).

### CROSS REFERENCE TO OTHER RELATED APPLICATIONS

Not Applicable

### STATEMENT REGARDING FEDERALLY SPONSORED RESEARCH OR DEVELOPMENT

Not Applicable

### BACKGROUND OF THE INVENTION

Electrical boxes provide a housing for electrical components such as outlets typically recessed within a wall, ceiling, or floor. These electrical boxes are found in both residential and commercial settings. The existing electrical boxes are often installed in inconvenient locations or they are not accessible due to furniture or physical constraints of the people who need to use said electrical boxes with outlets installed in them. The present invention allows for an electrical box assembly to be positioned on a wall in a place that is more convenient for electrical application, and have the ability for easy re positioning.

### FIELD OF INVENTION

The present invention relates to an electrical box assembly. More specifically, the invention relates to a rotating repositionable electrical box assembly that utilizes an electrical box connected to a rotating tubular electrical wire extension housing.

### BRIEF SUMMARY OF INVENTION

It is an advantage with the present invention to provide an electrical box assembly that provides for a quick installation on a wall in a more convenient location when an electrical box already exists nearby, but is inconveniently located. It is also advantageous to re position an electrical box assembly to accommodate different situations.

### BRIEF DESCRIPTION OF DRAWINGS

This invention is described by appended claims in relation to description of a preferred embodiment with reference to the following drawings, which are explained briefly as follows:

FIG. 1 is an isometric view of the embodiment of the invention

FIG. 2 is an exploded view of the upper portion of the invention

FIG. 3 is a view of the back side of the invention

FIG. 4 is an isometric view of potential installations

### DETAILED DESCRIPTION OF INVENTION

As required, detailed embodiments of the present invention are disclosed herein; however, it is to be understood that the disclosed embodiments are merely exemplary of the invention that may be embodied in various forms. The figures are not necessary to scale, some features may be exaggerated to show details of particular components. Therefore, specific structural and functional details disclosed herein are not to be interpreted as limiting, but merely as a basis for the claims and as a representative basis for teaching one skilled in the art to variously employ the present invention.

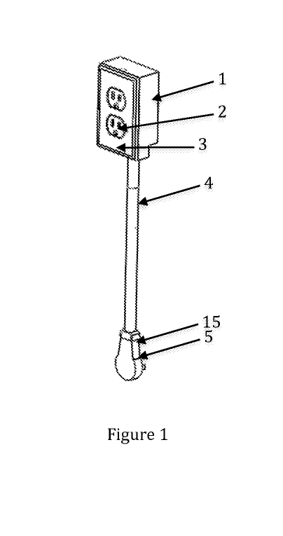

FIG. 1 illustrates an isometric view of the invention. The Repositionable Orbiting Outlet Electrical Box Assembly is comprised of 1 outlet housing, 2 outlet either a duplex 115V outlet or a GFCI duplex outlet (prior art) or other prior art outlet types. 3 outlet faceplate to match the corresponding outlet 2, 4 tubular rod that has a collar on the upper end and a 15 flanged end on the lower end that mates with 5 a rotating angle plug (reference U.S. Pat. No. 5,775,921).

The 1 outlet housing is capable of rotating so that when installed to a wall, the housing is capable of being orientated to that of a normal outlet installation. 4 Tubular rod's upper end collar snaps into the back side of the 1 outlet housing. 2 Outlet (prior art) attaches to the 1 Outlet housing by use of mechanical fasteners. 3 Outlet faceplate attaches to either the 2 outlet or 1 outlet housing by use of mechanical fasteners depending on the 2 outlet type. 5 360 Degree Rotating Angle Plug (prior art ref U.S. Pat. No. 5,775,921) will mate with an adhesive fastener in the 15 flanged end of the lower end of tubular rod.

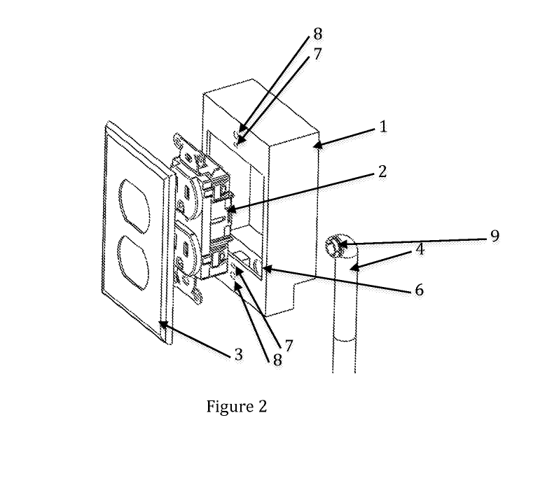

FIG. 2 depicts an exploded view of the outlet housing of the Repositionable Orbiting Outlet Electrical Box Assembly, 2 Outlet (prior art) will be attached to the 1 outlet housing with a mechanical fastener that mates with 7 attachment hole for standard duplex outlet or 8 attachment hole for GFCI 115V outlet. 9 Tubular rod collar will clip into 6 hole in the back side of 1 outlet housing.

9 Tubular rod collar will rotate up to 360 degrees allowing 1 housing to be installed in vertical orientation to that of a standard wall electrical receptacle installation.

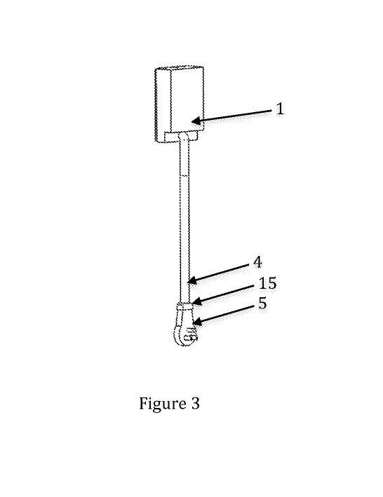

FIG. 3 depicts the back side of the repositionable orbiting outlet assembly. 5 360 degree rotating angle plug (prior art reference U.S. Pat. No. 5,775,921) will mate into the 15 flanged end of 4 tubular rod. 5 360 degree rotating angle plug allows the Repositionable Orbiting Outlet assembly to be connected to an existing outlet while positioning the 1 outlet housing in a desired location within the circumferential orbit set forth by 4 tubular rod.

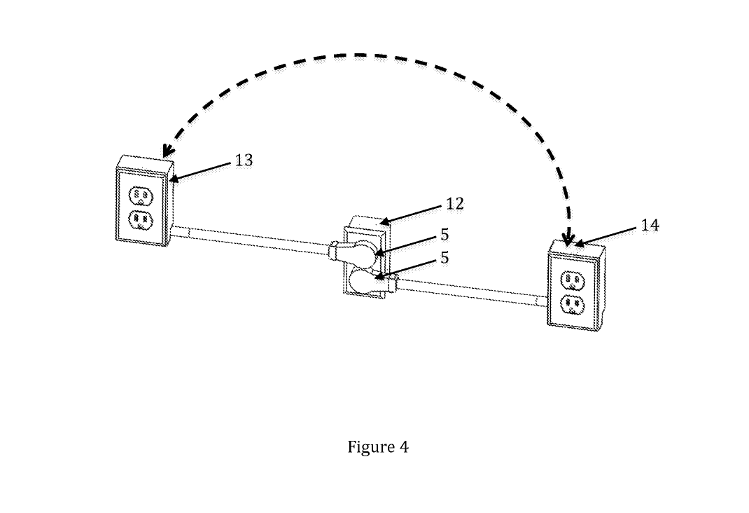

FIG. 4 depicts an isometric view of potential installations of the Repositionable orbiting outlet assembly. The Repositionable Orbiting Outlet Assembly will be able to rotate about an 12 existing wall outlet with the use of 5 360 degree rotating angle plug (prior art reference U.S. Pat. No. 5,775,921). 13 Installation location shows repositionable orbiting outlet assembly rotated counter-clockwise 90 degrees while 14 installation location shows the repositionable orbiting outlet assembly rotated clockwise 90 degrees.

1. A moveable repositionable rotating electrical box assembly, which adheres to a wall, comprising of an electrical box connected to a tubular electrical wire housing by a rotating collar; wherein the rotating collar allows the electrical box to rotate in a desired orientation, and the tubular electrical wire housing extends towards an existing wall outlet which flanges at the end closest to an existing wall outlet.

2. The electrical box assembly as defined in claim 1, wherein the electrical box is sized for receiving different electrical outlet types (prior art), including but not limited to GFCI outlets (prior art) or usb outlet types (prior art).

3. The electrical box assembly as defined in claim 2, wherein the electrical outlet (prior art) is attachable by mechanical fasteners on assembly.

4. The electrical box assembly as defined in claim 3, wherein the back of the box is flat and able to receive adhesive strips (prior art) to adhere to a wall.

5. The electrical box assembly as defined in claim 4, wherein the box may also be connected to wall by screw attachment.

6. The electrical box assembly as defined in claim 5, wherein the back of the electrical box has an indention on lower back portion of box.

7. The electrical box assembly as defined in claim 6, wherein the electrical box has a circular attachment point on the indention described in claim 6.

8. The electrical box assembly as defined in claim 7, wherein the circular attachment point on the assembly is sized to accommodate insulated electrical wires passing through port connected to the electrical outlet (prior art) described in claim 2.

9. The electrical box assembly as defined in claim 1, wherein a tubular electrical wire housing is attached to the circular attachment point by snap in design.

10. The electrical box assembly as defined in claim 9, wherein the tubular round electrical wire housing has the ability to rotate 180 degrees.

11. The electrical box assembly as defined in claim 10, wherein the tubular round electrical wire housing extends towards an existing outlet.

12. The electrical box assembly as defined in claim 11, wherein the tubular round electrical wire housing is paintable.

13. The electrical box assembly as defined in claim 12, wherein the tubular round electrical wire housing can be various lengths.

14. The electrical box assembly as defined in claim 13, wherein the tubular round electrical wire housing flanges at the end closest to the existing outlet.

15. The electrical box assembly as defined in claim 12, wherein the tubular round electrical wire housing flange accommodates rotating plugs (prior art ref U.S. Pat. No. 5,775,921).
